(19) United States
(12) Patent Application Publication
(10) Pub. No.: US 2008/0187781 A1
(43) Pub. Date: Aug. 7, 2008

(54) Magnetic recording head and media overcoat

(75) Inventors: Shide Cheng, Fremont, CA (US); Zhu Feng, Pleasanton, CA (US); Ellis T. Cha, San Ramon, CA (US)

Correspondence Address: STEPHEN B. ACKERMAN, 28 DAVIS AVENUE, POUGHKEEPSIE, NY, 12603, US

(73) Assignee: SAE Magnetics (HK) Ltd.

(21) Appl. No.: 11/702,247

(22) Filed: Feb. 5, 2007

(51) Int. Cl. C23C 16/34

(52) U.S. Cl. 428/812; 427/527

(57) ABSTRACT

A method for forming a protective bilayer on a substrate that is a magnetic read/write head or a magnetic recording medium. The bilayer is formed as an adhesion enhancing and corrosion resistant underlayer and a protective diamond-like carbon (DLC) overlayer. The underlayer is formed of silicon oxynitride, having the general formula SiOₓN_{y}, where x can be within the range between 0.02 and 2.0 and y is in the range between approximately 0.01 and 1.5. By adjusting the values of x and y the underlayer contributes to such qualities as strong chemical bonding between the substrate and the DLC, wear and corrosion resistance, chemical and mechanical stability and low electrical conductivity. The underlayer may be formed by various methods such as reactive ion sputtering, plasma assisted chemical vapor deposition, reactive pulsed laser deposition, plasma surface treatment and plasma immersion ion implantation.

### RELATED PATENT APPLICATION

This application is related to Docket Number SM 06-006, Filing Date Jan. 18, 2007, Ser. No. 11/655,025, assigned to the same assignee as the present application.

### BACKGROUND OF THE INVENTION

1. Field of the Invention

This invention relates to the fabrication of hard disk drives (HDD), particularly to a method of protecting a magnetic head and magnetic disks by use of a diamond-like coating on an underlayer that also enhances adhesion and serves as a corrosion barrier.

2. Description of the Related Art

Reducing the head-to-disk spacing (fly height) between a magnetic read/write head and the surface of a magnetic disk rotating beneath it has been one of the major approaches in achieving ultra-high recording density in a hard disk drive (HDD) storage system. For a commercially available HDD with 160 GBytes capacity, the fly height is on the order of 10 nanometers (nm). Maintaining such a small spacing between a rapidly spinning disk and a read/write head literally flying above it is difficult and an occasional contact between the disk surface and the head is unavoidable. Such contact, when it does occur, can lead to damage to the head and the disk and to the loss of recorded information on the disk. To minimize the head and disk damage, a thin layer of DLC (diamond-like carbon) coating is applied to both the surface of the head and the surface of the disk. This DLC also serves to protect the magnetic materials in the head from corrosion by various elements within the environment. Given the importance of the role of the DLC, it is essential that it is hard, dense and very thin, the thinness being required to satisfy the overall fly height requirement while not using up any of the allotted spacing. Currently a DLC coating between 20-30 angstroms is found in the prior art.

Conventionally, DLC coatings thicknesses are greater than 50 angstroms and for that thickness range there is a high degree of internal stress, leading to poor adhesion with the substrate materials of the head as well as to other substrates to which they may be bonded. Because of high internal stress and thermal stress an adhesion layer is required. For example, in applications to cutting edges and drilling tools, where the DLC thickness is in the micron range and the working temperature can reach a few hundred degrees Celsius, the coefficient of thermal expansion (CTE) of the adhesion layer also plays an important role. For these reasons, Japanese Patents JP 2571957, Itoh et al., (U.S. Pat. No. 5,227,196) and JP 3195301 have proposed Si, SiOx, SiC and SiNx for such an adhesion layer. In particular, Japanese Patent JP2571957 teaches the introduction of gaseous silicide onto a base material having an oxide surface as a substrate and the formation of a buffer layer of amorphous silicon using a plasma as a decomposing medium. Thereafter, gaseous hydrocarbon is introduced and a carbon containing coating film is formed on the buffer layer.

Itoh (cited above) teaches a lamination of films comprising at least two film layers for the purpose of controlling internal stresses. In one embodiment the hydrogen content of a silicon nitride layer is controlled to obtain optimum properties of the silicon nitride layer as a buffer layer between a carbon layer and an oxide substrate.

JP3195301 teaches the formation of a carbon film on a substrate by the interposition of a film having a lower internal stress. In an embodiment, a silicon nitride film is used as the interposing film of lower stress. The film is formed using a hydrogen silicide gas introduced into a reaction chamber.

Ishiyama (US Patent Application 2006/0063040) discloses a carbon-based protection layer of hydrogenated carbon nitride for better adhesion. Hwang et al. (US Patent Application 2005/0045468) teaches a Si adhesion layer for a DLC. Hwang et al. (US Patent Application 2002/0134672) discloses Si, Al₂O₃, SiO₂, or SiNₓ as an adhesion layer beneath a DLC layer. David et al. (U.S. Pat. No. 5,609,948) describes a SiC adhesion layer under a DLC layer.

For use in magnetic heads the underlayer should have the following properties:

1. Electrical isolation property. For magnetic heads, electrical isolation must be provided for the magnetic metal alloy layers, such as those layers comprising a magnetoresistive read head based on the giant magnetoresistance (GMR) effect, or those comprising a device based on the tunneling magnetoresistive (TMR) effect. Electrical short circuits between these layers and surrounding HDD components will damage the head or similar device. For this reason, the protection layers, especially the underlayer, should be insulating or semi-insulating. However, due to the semiconductor properties of Si, the surface shunting of a Si adhesion layer can introduce noise, such as the so-called popcorn noise, into the GMR or TMR reader.
2. Anti-corrosion property. DLC films, particularly those produced through the filtered cathodic vacuum arc (FCVA) process of the prior art, are often embedded with micro- or nano-particles. These particles can result in pinholes and corrosion of the materials used in forming the magnetically active layers, such as NiFe and NiCoFe. The anti-corrosion property of the underlayer, if it can be provided, is therefore of crucial importance to maintaining the performance integrity of the sensor.
3. Anti-wear property. With the total thickness of the adhesion layer and the DLC layer being reduced to the sub-30 angstrom range, literally every atom counts for the protection. It is therefore very important that the adhesion layer has both chemical stability for corrosion protection and high hardness for tribological advantage. It is the purpose of the present invention to provide a new class of materials as adhesion layers to replace the Si and related materials described in the prior art cited above.

### SUMMARY OF THE INVENTION

The first object of the present invention is to provide a thin protective layer for a magnetic read/write head or a magnetic recording medium to protect them from inadvertent contact between the head and the medium surface.

The second object of the present invention is to provide such a protective layer formed as a bilayer, wherein an overlayer is primarily a protective layer and an underlayer is primarily an adhesion enhancing layer and a corrosion resistant layer.

The third object of the present invention is to provide such a bilayer wherein inherent high resistivity of the underlayer eliminates surface shunting, thereby reducing noise, such as popcorn noise, from the read/write head.

A fourth object of the present invention is to provide such a bilayer wherein the underlayer forms a strong and stable chemical bond with the overlayer.

A fifth object of the present invention is to provide methods for forming a protective bilayer that satisfies all of the above objects.

The objects of this invention will be achieved by the use of a class of materials, the silicon oxynitrides, of general formula SiOₓN_{y}, to form the adhesion enhancing and corrosion protection underlayer of a protective bilayer. Silicon oxynitride can be effectively bonded to the DLC and to the read/write head substrate to form a strong and stable bond. It has the requisite chemical and mechanical properties to satisfy the objects of the invention set forth above.

Because of the affinity between carbon and silicon atoms, SiOₓN_{y} exhibits good adhesion to DLC films, forming Si—C bonds. In addition, silicon has also been proven to have good adhesion to the various substrate materials used in the fabrication of a read/write head, including materials such as AlTiC, Al₂O₃, NiFe, NiFeCo and others of a comparable nature. Further, the chemical, mechanical and physical properties of the silicon oxynitrides can be tailored by varying the oxygen and nitrogen concentrations, x and y, in the formula. For reference and comparison purposes, FIG. 1 provides a convenient listing of several relevant mechanical and electrical properties of various materials that are used in the fabrication of a magnetic read/write head.

An important function of thin protective films, such as the bilayer of the present invention, is to provide corrosion protection. Compared to either silicon or amorphous silicon, SiO₂ and Si₃N₄ are more stable and corrosion resistant and, therefore, corrosion protective. For example, the etch rate of Si in a basic solution is much higher than that of either SiO₂ or Si₃N₄; specifically in KOH solutions (33.3% by wt., at 80° C.) for Si in the (100) plane the etch rate is 11000 angstroms/min, while for thermoxide SiO₂ it is about 77 angstroms/min and for Si rich silicon nitride and stoichiometric silicon nitride the etch rate is virtually zero. (K. R. Wiliams, “Etch rate for micromachining processing-part II” Journal of Microelectromechanical Systems, 12(67), pp. 761-778, 2003).

Dipping tests can reveal the corrosion resistance of the protective coating. Such tests have been carried out in both acidic (formic acid) and basic (baking soda) conditions. With the same thickness of 30 angstroms, a SiON/DLC bilayer has statistically shown better corrosion resistance than the conventional Si/DLC bilayer (see FIG. 3).

The hardness of SiOₓN_{y} can be varied from 6 GPa (SiO₂) to more than 20 GPa (SiN_{y}). Similarly, the stress in a thin film of SiOₓN_{y} can be varied (tuned) from a tensile stress of +0.9 Gpa for SiN_{y} to a compressive stress of −0.3 Gpa for SiO₂. By comparison, a-Si has a compressive stress of about +1.0 Gpa (R. T. Howe et al., “Stress in polycrystalline and amorphous silicon thin films”, Journal of Applied Physics, 54(8) pp. 4674-4675, 1983). The tunability of other properties of SiOₓN_{y} has also been well demonstrated, for example its optical index of refraction can vary between 1.45 for SiO₂ to 2.0 for SiN_{y} to 2.4 for Si-rich SiOₓN_{y}.

As noted above, with the total thickness of the underlayer and the DLC layer being reduced to the sub-30 angstrom range, literally every atom counts in providing the protection. Oxygen and Nitrogen are among the smallest atoms (FIG. 4). In amorphous SiO₂, two O atoms roughly occupy the space of one Si atom so more small atomes can be inserted for a given thickness. For wear durability of the DLC overcoat, the adhesion strength of the overcoat to the substrate is an important consideration. The wear durability in the present invention has been demonstrated by the use of nano-wear experiments using the Hysitron Triboindenter. With the same 20 micro-Newton load and 20 wear cycles applied to equal thicknesses of conventional Si/DLC bilayers and the SiOₓN_{y}/DLC of the present invention, the SiOₓN_{y}/DLC of the present invention shows better nano-wear durability.

Because SiON is more insulating than Si, surface shunting and its related noise can be greatly decreased. FIG. 5 shows results of a Quasi-Static Test carried out for both conventional Si/DLC bilayers (shaded bars) and SiON/DLC bilayers (unshaded bars) of the present invention (260 sliders of each kind) and the results show clear reduction in the frequency of popcorn noise in the SiON/DLC protected sliders.

The SiOₓN_{y} underlayer can be prepared by a variety of methods, including:

1. Reactive sputtering of Si with metal, metal oxide or metal nitride targets within an Ar/O₂/N₂ atmosphere.
2. Plasma enhanced chemical vapor deposition (PECVD), low pressure chemical vapor deposition (LPCVD), plasma immersion ion implantation (PIII), plasma immersion ion implantation deposition (PIIID).
3. Plasma treatment of a Si surface by an ion-beam plasma, capacitively coupled plasma (CCP), inductively coupled plasma (ICP) and electron cyclotron resonance (ECR) plasma.

### BRIEF DESCRIPTION OF THE DRAWINGS

The objects, features, and advantages of the present invention are understood within the context of the Description of the Preferred Embodiment as set forth below. The Description of the Preferred Embodiment is understood within the context of the accompanying figures, wherein:

FIG. 1 is a table listing several relevant properties of materials used in forming the read/write head and its protective coatings.

FIGS. 2a and 2b are schematic flow charts outlining the steps in forming the protective bilayer of the present invention.

FIG. 3 presents a comparison of the corrosion rates for prior art protective layers and the protective layers of the present invention.

FIG. 4 shows the atomic radii of the elements used in the present invention.

FIG. 5 shows a comparison between the popcorn noise associated with prior art protective layers and those of the present invention.

FIG. 6 is a schematic illustration of an interface between a read/write head and a magnetic disk, each protected by the bilayer of the present invention.

FIG. 7 is a schematic illustration of a preferred embodiment of the invention using ion-beam sputtering, focused ion-beam sputtering or pulsed ion-beam sputtering.

FIG. 8 is a schematic illustration of a preferred embodiment of the invention using a high energy laser.

FIG. 9 is a schematic illustration of a preferred embodiment of the invention in which a sputtered Si film on a plurality of read/write heads or magnetic media is then exposed to a mixed Ar/O₂/N₂ plasma, a sequence comprising an Ar/N₂ plasma and Ar/O₂ plasma (or the reverse sequence), where such plasmas are applied as an inductively coupled plasma (ICP), a capacitively coupled plasma (CCP) or an electron cyclotron resonance (ECR) plasma.

### DESCRIPTION OF THE PREFERRED EMBODIMENTS

The preferred embodiments of the present invention teach methods of fabricating a thin protective bilayer over a magnetic read/write head or a magnetic medium wherein the protective bilayer comprises a SiOₓN_{y} adhesion enhancing and corrosion resisting underlayer over which is formed a hard, protective diamond-like carbon (DLC) overlayer (also referred to as an overcoat).

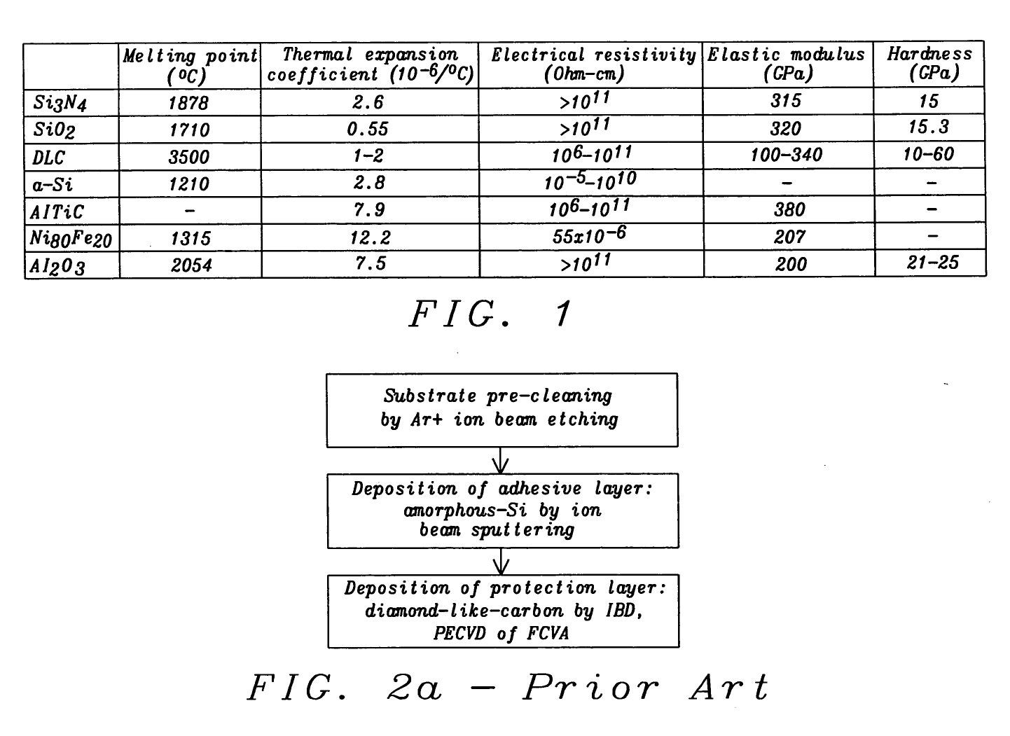

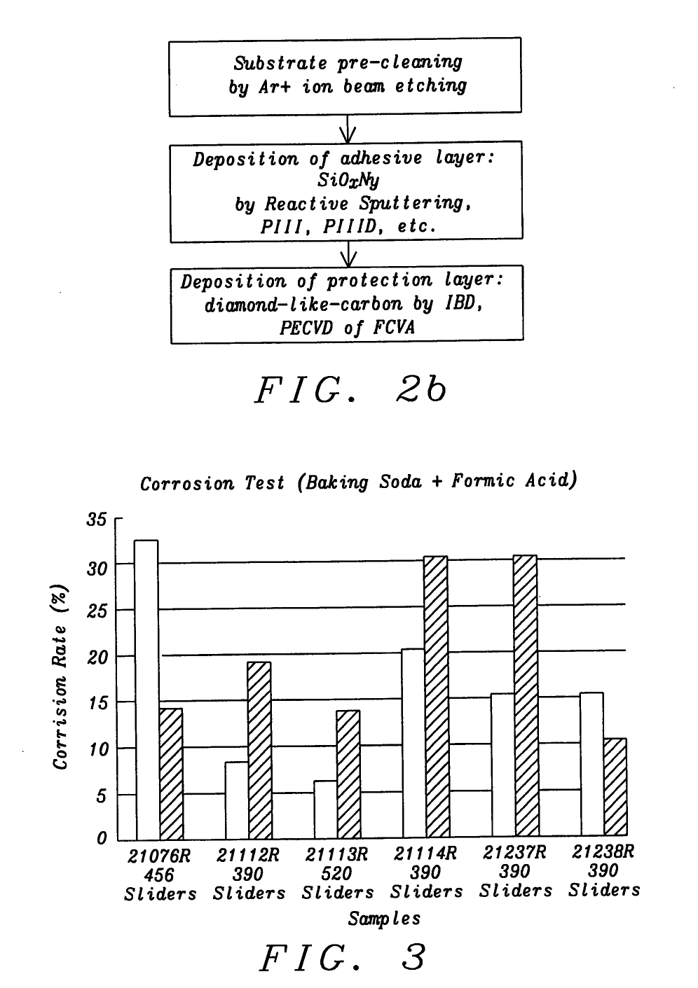

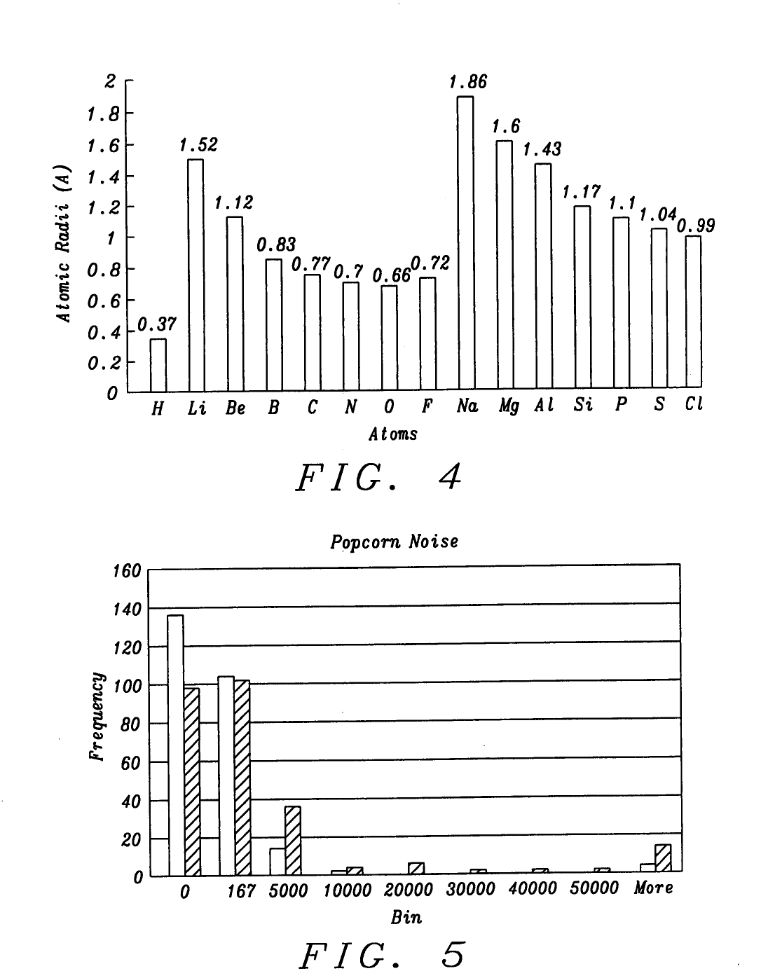

Amorphous Si (a-Si) is widely used as an adhesion layer in the magnetic recording industry to promote the adhesion of a DLC layer to the substrate of a magnetic read/write head. Referring to FIG. 2a there is indicated a sequence of three steps by which the prior art protective coating is formed on a read/write head. In the prior art, the coating process begins with the cleaning of the head substrate using an Ar⁺ ion beam. Following this cleaning process, an adhesion layer of amorphous Si is deposited using ion-beam sputtering and then a DLC overlayer is deposited using ion-beam deposition (IBD) or PECVD or, more preferably, filtered cathodic vacuum arc (FCVA).

The preferred embodiments of the present invention differ from the prior art IBD deposition of a-Si on a read/write head substrate and will also include the deposition on a substrate that includes a magnetic recording medium as well as a read/write head. Referring to FIG. 2b, there is shown a sequence of three steps that produces the protective bilayer of the present invention.

1. Substrate pre-cleaning using an Ar⁺ ion beam as an etching mechanism, wherein the substrate can be the surface of a read/write head or a magnetic medium.
2. Deposition of an adhesion enhancing and corrosion resistant underlayer of SiOₓN_{y} using reactive ion sputtering of Si with silicon, silicon oxide or silicon nitride targets within an Ar/O₂/N₂ atmosphere, plasma enhanced chemical vapor deposition (PECVD) or reactive pulsed laser deposition. Or, plasma treatment of an a-Si film by an ion-beam plasma, a capacitively coupled plasma (CCP), an electron cyclotron resonance (ECR) plasma, an inductively coupled plasma (ICP) or by plasma immersion ion implantation/deposition (PIIID).
3. Deposition of a protective overlayer of DLC, using ion beam deposition (IBD), plasma enhanced chemical vapor deposition (PECVD) or filtered cathodic vacuum arc (FCVA).

The following nine embodiments of the present invention are all methods by which a protective bilayer can be formed on a magnetic read/write head or magnetic medium that will meet all the objects of the invention set forth above. In all of the embodiments, the protective layer is formed on an appropriate substrate surface of the read/write head or recording medium, such as an air-bearing layer surface (ABS) that has been cleaned by an appropriate method such as Ar⁺ beam etching. It is also understood that there is preferably a plurality of read/write heads mounted on a holder and simultaneously treated by the method.

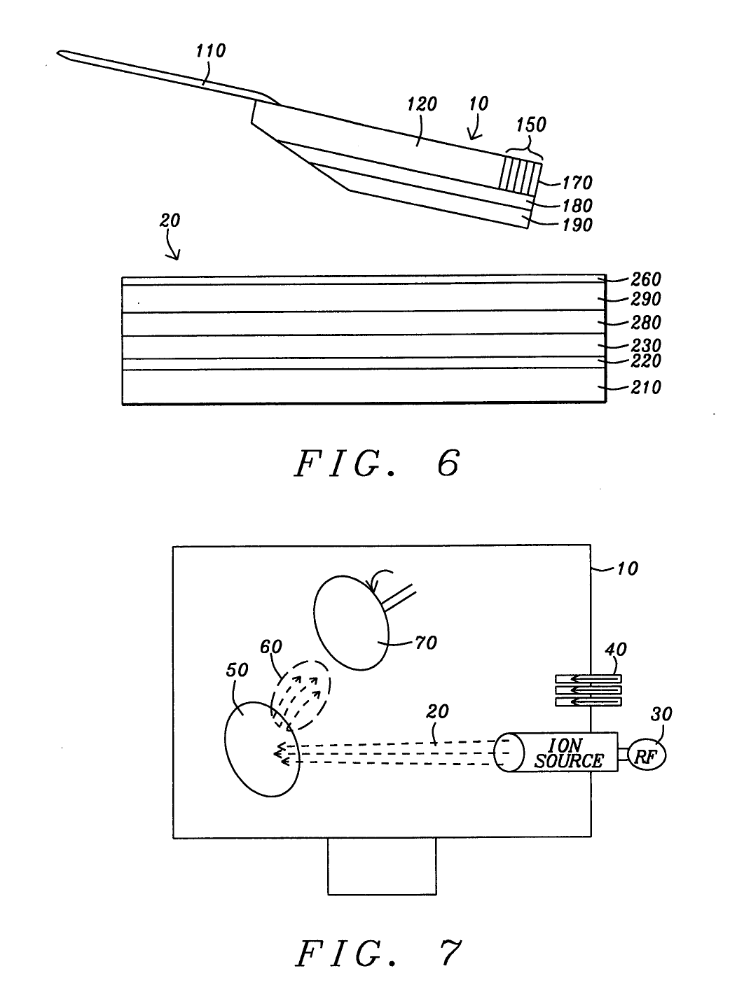

For purposes of schematically illustrating the objects of the application of any of the following embodiments of the present invention, FIG. 6 schematically shows a read/write head positioned above a magnetic recording medium in a position assumed by the head and the medium while the hard disk drive (HDD) is in operation and the magnetic recording medium is in motion beneath the head. The figure illustrates a magnetic head-disk interface (not drawn to scale), where a magnetic read/write head slider (10) is mechanically attached to its suspension (110). The slider is built on AlTiC substrate (120) with shielded GMR or TMR reader and writer (150) and an Al₂O₃ overcoat (170). The reader shield, the reader, and writer materials are mainly formed of magnetic materials comprising various alloys and compounds of Ni—Fe—Co that are subject to corrosion when exposed to environmental conditions. The slider is coated with an underlayer (180) and DLC overcoat (190).

On the other hand, the magnetic recording medium (a disk (20) in these embodiments)) rotating beneath the slider is built on a glass or aluminum substrate (210) on top of which is a first underlayer (220) (not the underlayer of this invention) and a magnetic layer (230), The surface of the magnetic layer (230) is protected by a second underlayer (280), which is the underlayer of this invention, and DCL overcoat (290), both formed by the method of the present invention. To minimize the abrasion with the slider head, a lube (lubrication) layer (260) is applied on the magnetic disk. The present invention provides the underlayer for both the slider (180) and for the magnetic disk (280) and the DLC layer formed on them.

### First Preferred Embodiment

Referring now to FIG. 7, there is shown a schematic perspective drawing of an apparatus within which the protective bilayer of the present invention can be formed on a magnetic read/write head or recording medium.

The first preferred embodiment of this invention uses a deposition chamber (10) into which an ion beam, which in this embodiment is an Ar⁺ beam (20), is injected. The beam is produced by a RF source (30) and accelerated by voltages that range from 300 V to 1200 V. Injection ports (40) allow the injection of O₂ and N₂ gases into the chamber (10) with flow rates between 0 and 20 sccm, and different ratios, x/y, depending upon the desired form of the SiOₓN_{y} underlayer. The Ar⁺ beam is directed at a sputtering target of SiO₂ (50) and the sputtered atoms (60) impinge on a rotatably mounted deposition target (70) that can be read/write heads, a plurality of which can be mounted as uncut sliders on a rotatable holder that can be rotated for uniformity of the deposition. Alternatively, (70) can also be a similarly mounted magnetic recording medium, such as the magnetic disk of FIG. 6. Values of x between 0.02 and 2.0 and values of y between 0.01 and 1.5 have produced underlayers meeting the objects of the invention. It is also noted that x and y can be varied as the deposition process proceeds to produce adhesion layers with compositions that are a function of layer thickness. In all these formations an overall thickness of the underlayer that does not exceed 50 angstroms produces results that meet the objects of the invention. An underlayer thickness that is less than 20 angstroms is most preferable. Subsequent to the deposition of the underlayer, a layer of DLC is formed on the underlayer to produce a bonded bilayer that meets the objects of the invention.

### Second Preferred Embodiment

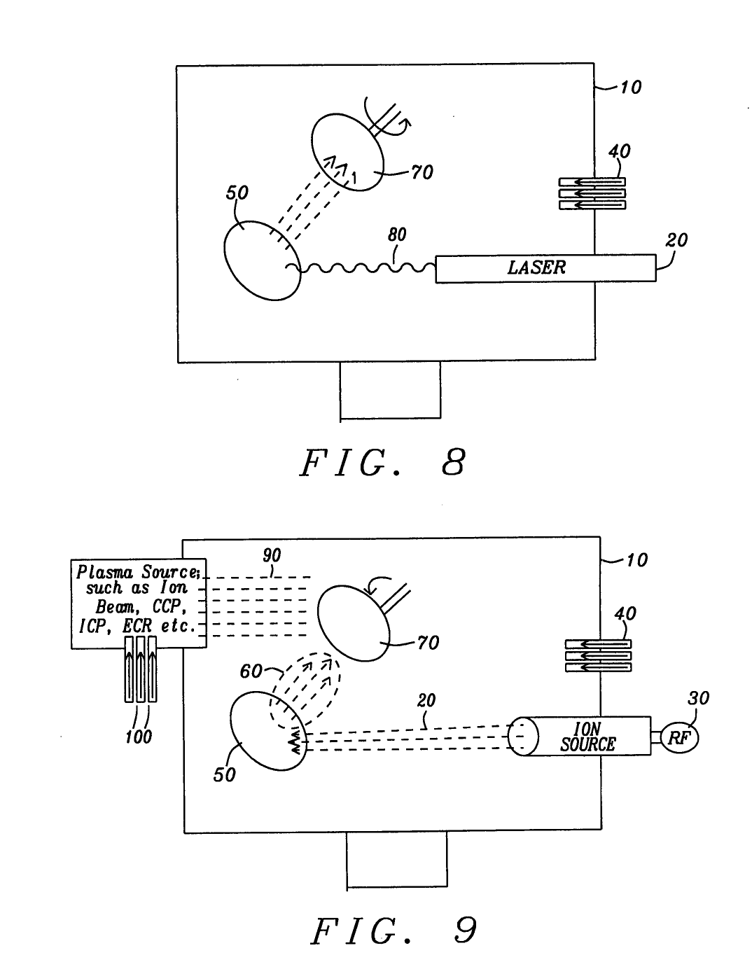

In a second preferred embodiment, the apparatus of FIG. 8 is used as above, but the sputtering target material (50) is Si₃N₄. A ion beam, which in this embodiment is an Ar⁺ beam (20) is injected using voltages between 300 V and 1200 V and the O₂ and N₂ gases are injected into the chamber (10) with flow rates between 0 and 20 sccm, and different ratios, x/y, depending upon the desired form of the SiOₓN_{y} underlayer. The Ar⁺ beam is directed at a sputtering target of Si₃N₄ (50) and the sputtered Si and N atoms (60) impinge on the rotatably mounted deposition target (70) of read/write heads in the presence of the injected O₂ and N₂ gases to produce the desired SiOₓN_{y} underlayer. A plurality of the read/write heads are mounted as a plurality of uncut sliders on a rotatable holder for uniformity of the deposition. Alternatively, (70) can also be a magnetic recording medium such as a magnetic disk. Values of x between 0.02 and 2.0 and values of y between 0.01 and 1.5 have produced underlayers meeting the objects of the invention. It is also noted that x and y can be varied as the deposition process proceeds to produce underlayers with compositions that are a function of underlayer thickness. In all these formations an overall thickness of the underlayer that does not exceed 50 angstroms produces results that meet the objects of the invention. An underlayer thickness that is less than 20 angstroms is most preferable.

Subsequent to the formation of the underlayer, a DLC overlayer is formed on the underlayer using methods cited above.

### Third Preferred Embodiment

The third preferred embodiment of this invention uses the apparatus of FIG. 7, comprising a deposition chamber (10) into which an ion beam can be injected while injection ports (40) allow the injection of O₂ and N₂ gases with flow rates between 0 and 20 sccm, and different ratios, x/y, depending upon the desired form of the SiOₓN_{y} underlayer. In this embodiment, however, the ion beam is a high energy scanning, focused ion beam (20) that is directed at a sputtering target of Si (50) and the sputtered atoms (60) impinge on the rotatably mounted deposition target (70) of read/write heads that are mounted as uncut sliders on a rotatable holder for uniformity of the deposition. Alternatively, (70) can also be a magnetic recording medium such as a magnetic disk. To avoid poisoning the sputtering target and to eliminate hysteresis effects associated with the deposition, there is used a high energy scanning focused ion beam as described by T. Nyberg et al. (US Patent Application 2004/0149566 which is incorporated by reference here in its entirety). Values of x between 0.02 and 2.0 and values of y between 0.01 and 1.5 have produced underlayers meeting the objects of the invention. It is also noted that x and y can be varied as the deposition process proceeds to produce underlayers with compositions that are a function of underlayer thickness. In all these formations an overall thickness of the underlayer that does not exceed 50 angstroms produces results that meet the objects of the invention. An underlayer thickness that is less than 20 angstroms is most preferable.

### Fourth Preferred Embodiment

The fourth preferred embodiment of this invention uses the apparatus of FIG. 7, which comprises a deposition chamber (10) into which an ion beam can be injected while injection ports (40) allow the injection of O₂ and N₂ gases with flow rates between 0 and 20 sccm, and different ratios, x/y, depending upon the desired form of the SiOₓN_{y} underlayer. In this embodiment, however, the ion beam (20) is produced by a pulsed ion source (30) with high instantaneous power, the beam is directed at a sputtering target of Si (50) and the sputtered atoms (60) impinge on the rotatably mounted deposition target (70) of read/write heads, that are mounted on a rotatable holder as a plurality of uncut sliders for uniformity of the deposition. Equally, deposition target (70) can be a magnetic medium disk mounted on the holder. To avoid poisoning the sputtering target and to eliminate hysteresis effects associated with the deposition, there is used a high instantaneous power pulsed ion source as described by V. Kousnetsov et al. (U.S. Pat. No. 6,296,742 which is incorporated by reference here in its entirety. Values of x between 0.02 and 2.0 and values of y between 0.01 and 1.5 have produced underlayers meeting the objects of the invention. It is also noted that x and y can be varied as the deposition process proceeds to produce underlayers with compositions that are a function of underlayer thickness. In all these formations an overall thickness of the underlayer that does not exceed 50 angstroms produces results that meet the objects of the invention. An underlayer thickness that is less than 20 angstroms is most preferable.

### Fifth Preferred Embodiment

The fifth preferred embodiment of this invention uses the apparatus of FIG. 8, which comprises a deposition chamber (10) into which a laser (20) can direct a beam of electromagnetic radiation (80) at a Si, SiO₂ or Si₃N₄ sputtering target (50) while injection ports (40) allow the injection of O₂ and N₂ gases with flow rates between 0 and 20 sccm, and different ratios, x/y, depending upon the desired form of the SiOₓN_{y} underlayer. In this embodiment, the laser can be a high energy laser such as a CO₂ laser, an excimer laser, etc and the atoms ejected (60) by the laser beam impinge on the rotatably mounted deposition target (70) of read/write heads, mounted as uncut sliders on a rotatable holder for uniformity of the deposition. Alternatively, (70) can also be a magnetic recording medium, such as a disk. The laser fluence can be between approximately 2 and 5 J/cm². Values of x between 0.02 and 2.0 and values of y between 0.01 and 1.5 have produced underlayers meeting the objects of the invention. It is also noted that x and y can be varied as the deposition process proceeds to produce underlayers with compositions that are a function of underlayer thickness. In all these formations an overall thickness of the underlayer that does not exceed 50 angstroms produces results that meet the objects of the invention. An underlayer thickness that is less than 20 angstroms is most preferable.

### Sixth Preferred Embodiment

Referring to FIG. 9, there is shown a schematic perspective drawing of an apparatus within which there is carried out a two-step process of forming the protective bilayer on a magnetic read/write head in accord with a sixth preferred embodiment.

The sixth preferred embodiment of this invention uses the deposition chamber (10) of FIG. 9 into which a reactive ion beam, such as the Ar⁺ beam (20) of this embodiment, is injected. The beam is produced by a RF source (30) and accelerated by voltages that range from 300 V to 1200 V. The beam (20) impinges on a Si sputtering target (50) causing Si atoms to be sputtered onto a rotatably mounted deposition target (70) that can be a plurality of rotatably mounted magnetic read/write heads, typically as a plurality of uncut sliders, mounted on a rotatable holder for uniform deposition. Alternatively, (70) also can be a rotatably mounted magnetic recording medium, such as a magnetic disk, with the deposition being made thereon.

After deposition of the Si sputtered film on the read/write heads or disk, the Si film is then exposed to a plasma (90) of Ar, O₂ and N₂ gases (Ar being the carrier gas) with different ratios of the O₂ and N₂ gases respectively, depending upon the desired form of the SiOₓN_{y} layer (i.e. the process constituting plasma surface treatment of the already deposited Si film). The plasma can be generated and applied by the use of any of a number of methods known in the art, such as plasma formation by an ion beam, formation and application of a capacitively coupled plasma (CCP), formation of an electron cyclotron resonance (ECR) plasma or formation and application of an inductively coupled plasma (ICP).

Values of x between 0.02 and 2.0 and values of y between 0.01 and 1.5 have produced underlayers meeting the objects of the invention. It is also noted that x and y can be varied as the deposition process proceeds to produce underlayers with compositions that are a function of underlayer thickness. In all these formations an overall thickness of the underlayer that does not exceed 50 angstroms produces results that meet the objects of the invention. An underlayer thickness that is less than 20 angstroms is most preferable.

### Seventh Preferred Embodiment

The seventh preferred embodiment of this invention uses the deposition chamber (10) of FIG. 9 into which an ion beam, such as the Ar⁺ beam (20) of the present embodiment is injected. The beam is produced by a RF source (30) and accelerated by voltages that range from 300 V to 1200 V. The beam (20) impinges on a Si sputtering target (50) causing Si atoms to be sputtered onto a rotatably mounted deposition target (70) that can be a plurality of rotatably mounted magnetic read/write heads, mounted, typically as a plurality of uncut sliders, on a rotatable fixture for uniform deposition. Alternatively, sputtering target (70) is a magnetic medium such as a magnetic disk mounted on the rotatable holder and the deposition being made thereon.

After the deposition of the Si sputtered film on the read/write heads the film is sequentially exposed to a plasma (90) of Ar/O₂ gases followed by a plasma of Ar/N₂ gases or, alternatively, the reverse sequence of Ar/N₂ gases followed by Ar/O₂ gases. These plasmas are formed using methods such as those described above with reference to the sixth preferred embodiment, such as plasma formation by an ion beam, formation and application of a capacitively coupled plasma (CCP), formation of an electron cyclotron resonance (ECR) plasma or formation and application of an inductively coupled plasma (ICP), and each plasma is applied to the Si film for different time durations depending upon the desired form of the SiOₓN_{y}. Values of x between 0.02 and 2.0 and values of y between 0.01 and 1.5 have produced adhesion layers meeting the objects of the invention. It is also noted that x and y can be varied as the plasma process proceeds to produce underlayers with compositions that are a function of layer thickness. In all these formations an overall thickness of the layer that does not exceed 50 angstroms produces results that meet the objects of the invention. An underlayer thickness that is less than 20 angstroms is most preferable.

### Eighth Preferred Embodiment

The eighth preferred embodiment of this invention uses the deposition chamber (10) of FIG. 9 into which an ion beam, such as the Ar⁺ beam (20) of the present embodiment is injected. The beam is produced by a RF source (30) and accelerated by voltages that range from 300 V to 1200 V. The beam (20) impinges on a Si sputtering target (50) causing Si atoms to be sputtered onto a rotatably mounted deposition target (70) that is plurality of rotatably mounted magnetic read/write heads mounted, typically as a plurality of uncut sliders, on a rotatable fixture for uniform deposition. Alternatively, deposition target (70) is a rotatably mounted magnetic medium such as a magnetic disk and a deposition being made thereon.

The deposition of the Si sputtered film on the read/write heads is in the form of plasma immersion deposition, that is, the deposition is carried out in the presence of (immersion in) a plasma (90) of Ar, O₂ and N₂ gases (100) that is formed, using methods such as those described above with reference to the sixth preferred embodiment, such as plasma formation by an ion beam, formation and application of a capacitively coupled plasma (CCP), formation of an electron cyclotron resonance (ECR) plasma or formation and application of an inductively coupled plasma (ICP), and applied within the chamber (10) with different ratios of the O₂ and N₂ respectively, depending upon the desired form of the SiOₓN_{y}. Values of x between 0.02 and 2.0 and values of y between 0.01 and 1.5 have produced underlayers meeting the objects of the invention. It is also noted that x and y can be varied as the plasma process proceeds to produce adhesion layers with compositions that are a function of layer thickness. In all these formations an overall thickness of the layer that does not exceed 50 angstroms produces results that meet the objects of the invention. A layer thickness that is less than 20 angstroms is most preferable.

### Ninth Preferred Embodiment

Referring again to FIG. 7, there is shown a schematic perspective drawing of an apparatus within which there is now carried out a two-step process of forming the protective bilayer on a magnetic read/write head in accord with a ninth preferred embodiment.

The ninth preferred embodiment of this invention uses the deposition chamber (10) of FIG. 7 into which a reactive ion beam, such as the Ar⁺ beam (20) of this embodiment, is injected. The beam is produced by a RF source (30) and accelerated by voltages that range from 300 V to 1200 V. The beam (20) impinges on a Si sputtering target (50) causing Si atoms to be sputtered onto a rotatably mounted deposition target (70) that is a plurality of rotatably mounted magnetic read/write heads, typically in the form of a plurality of uncut sliders, mounted on a rotatable fixture for uniform deposition. Alternatively, the deposition target (70) is a magnetic medium, such as a magnetic disk, mounted on the holder for a deposition thereupon.

After deposition of the Si sputtered film on the read/write heads, the Si film is then exposed to an atmosphere of O₂ and N₂ gases introduced (40) into the chamber at different x/y ratios and for different time durations so that oxidation and nitridation of the Si film can be achieved with the desired values of x and y in the adhesion film of the form SiOₓN_{y}. Values of x between 0.02 and 2.0 and values of y between 0.01 and 1.5 have produced underlayers meeting the objects of the invention. It is also noted that x and y can be varied as the deposition process proceeds to produce underlayers with compositions that are a function of underlayer thickness. In all these formations an overall thickness of the underlayer that does not exceed 50 angstroms produces results that meet the objects of the invention. An underlayer thickness that is less than 20 angstroms is most preferable.

As is understood by a person skilled in the art, the preferred embodiments of the present invention are illustrative of the present invention rather than being limiting of the present invention. Revisions and modifications may be made to methods, processes, materials, structures, and dimensions through which is formed a protective layer on a magnetic read/write head, while still providing such a protective layer, formed in accord with the present invention as defined by the appended claims.

What is claimed is:

1. A protected magnetic read/write head or magnetic recording medium comprising:
the read/write head or recording medium;
a protective bilayer formed on said head or recording medium, the bilayer further comprising:
an underlayer formed as a layer of SiOₓN_{y} on an cleaned substrate surface of said head or recording medium;
a DLC outer layer formed on said underlayer.

2. The protected read/write head or recording medium of claim 1 wherein x is in the range between approximately 0.02 and 2.0 and y is in the range between approximately 0.01 and 1.5.

3. The protected read write head or recording medium of claim 1 wherein said underlayer is formed to a thickness less than approximately 50 angstroms.

4. The protected read write head or recording medium of claim 1 wherein said underlayer is formed to a thickness less than approximately 20 angstroms.

5. The protected read write head or recording medium claim 1 wherein x and y vary as a function of the underlayer thickness.

6. The protected read/write head or recording medium of claim 1 wherein said underlayer is formed by a process of sputtering, plasma immersion ion implantation, plasma immersion ion implantation deposition, plasma enhanced chemical vapor deposition, electron cyclotron resonance plasma deposition, or reactive pulsed laser deposition.

7. The protected read/write head or recording medium of claim 1 wherein said underlayer is both adhesion enhancing and corrosion resistant.

8. A method of forming a protected read/write head, a plurality of protected read/write heads or a protected magnetic recording medium comprising:
providing the read/write head, the plurality thereof or the magnetic medium;
cleaning appropriate surfaces of the read/write head, the plurality thereof or the magnetic recording medium;
forming on said surfaces an underlayer having the general formula SiOₓN_{y};
forming on said underlayer a DLC layer.

9. The method of claim 8 wherein x is in the range between approximately 0.02 and 2.0 and y is in the range between approximately 0.01 and 1.5.

10. The method of claim 8 wherein said underlayer is formed by a process comprising:
providing a vacuum deposition chamber that includes a rotatable holder, a sputtering target, an apparatus for injecting a beam of reactive ions at a chosen energy and directing said ions at said sputtering target, an apparatus for injecting various gases at chosen flow rates and maintaining said gases at desired relative concentrations within said chamber;
mounting said read/write head, said plurality of such heads or said magnetic recording medium on said holder;
directing said ion beam at a sputtering target of Si, SiO₂, or Si₃N₄;
introducing O₂ gas and N₂ gas at relative concentrations x and y respectively while said reactive ions are impinging on said target, thereby forming an underlayer of SiOₓN_{y} on said read/write head or plurality thereof.

11. The method of claim 10 wherein said reactive ion beam is a beam of Ar⁺ ions formed by sending said beam through a voltage of between approximately 600V to 1200V.

12. The method of claim 10 wherein said reactive ion beam is a high energy scanning focused ion beam applied so as to avoid poisoning the sputtering target and to eliminate hysteresis.

13. The method of claim 10 wherein said reactive ion beam is a high instantaneous power pulsed ion source applied so as to avoid poisoning the sputtering target.

14. The method of claim 10 wherein x and y are made to vary as said underlayer is being formed.

15. The method of claim 10 wherein said underlayer is formed to a thickness less than approximately 50 angstroms.

16. The method of claim 8 wherein said underlayer is formed by a process comprising:
providing a vacuum deposition chamber that includes a rotatable holder, a sputtering target, a laser for directing a high energy pulsed beam of electromagnetic radiation at said sputtering target, an apparatus for introducing various gases at chosen flow rates and maintaining said gases at desired relative concentrations within said chamber;
mounting said read/write head, said plurality of such heads or said magnetic recording medium on said holder;
directing said electromagnetic radiation at a sputtering target of Si;
injecting O₂ gas and N₂ gas at selected concentrations, while said electromagnetic radiation impinges on said target, thereby forming an underlayer of SiOₓN_{y} on said read/write head or plurality thereof.

17. The method of claim 16 wherein Ar is used as a carrier gas during the O₂ and N₂ injection process.

18. The method of claim 16 wherein x and y are made to vary as said underlayer is being formed.

19. The method of claim 16 wherein said underlayer is formed to a thickness less than approximately 50 angstroms.

20. The method of claim 16 wherein said laser is a CO₂ laser or an excimer laser.

21. The method of claim 16 wherein said high energy beam of radiation has an energy fluence between approximately 2 and 5 J/cm².

22. The method of claim 8 wherein said underlayer is formed by a process comprising:
providing a vacuum deposition chamber that includes a rotatable holder, a sputtering target, an apparatus for injecting a beam of reactive ions at a chosen energy and directing said ions at said sputtering target, an apparatus for forming a plasma within said chamber said plasma being formed of a mixture of O₂ gas and N₂ gas at selected concentrations;
mounting said read/write head, a plurality of such heads or a magnetic recording medium on said holder;
directing said reactive ion beam at a sputtering target of Si and forming, thereby, a Si layer on said read/write head, plurality thereof or magnetic recording medium; then
forming, subsequent to the formation of said Si layer, said plasma of O₂ gas and N₂ gas at selected concentrations, said Si layer being immersed in said plasma for a selected time duration and thereby forming an underlayer of SiOₓN_{y} on said read/write head or plurality thereof.

23. The method of claim 22 wherein Ar is used as a carrier gas during the O₂ and N₂ plasma formation process.

24. The method of claim 22 wherein said reactive ion beam is a beam of Ar⁺ ions formed by sending said beam through a voltage of between approximately 600V to 1200V.

25. The method of claim 22 wherein said plasma is applied as a sequence comprising an application of an Ar/O₂ plasma followed by an application of an Ar/N₂ plasma, each application being at a different time duration or as a sequence comprising an application of an Ar/N₂ plasma followed by an application of an Ar/O₂ plasma, each application being at a different time duration.

26. The method of claim 22 wherein said plasma is an ion beam plasma, an ECR plasma, an ICP, or a CCP.

27. The method of claim 8 wherein said underlayer is formed by a process comprising:
providing a vacuum deposition chamber that includes a rotatable holder, a sputtering target, an apparatus for injecting a beam of reactive ions at a chosen energy and directing said ions at said sputtering target, an apparatus for forming a plasma within said chamber said plasma being formed of a mixture of O₂ gas and N₂ gas at selected concentrations;
mounting said read/write head, said plurality of such heads or said magnetic recording medium on said holder;
directing said reactive ion beam at a sputtering target of Si and forming, thereby, a Si layer on said read/write head or plurality thereof;
forming said plasma of O₂ gas and N₂ gas, at selected concentrations, said Si layer being immersed in said plasma while said layer is being formed and thereby forming an underlayer of SiOₓN_{y} on said read/write head, said plurality thereof or said magnetic recording medium.

28. The method of claim 27 wherein Ar is used as a carrier gas during the O₂ and N₂ plasma formation process.

29. The method of claim 27 wherein said reactive ion beam is a beam of Ar⁺ ions formed by sending said beam through a voltage of between approximately 600V to 1200V.

30. The method of claim 27 wherein said plasma is an ion beam plasma, an ECR plasma, an ICP, or a CCP.

31. The method of claim 8 wherein said underlayer is formed by a process comprising:
providing a vacuum deposition chamber that includes a rotatable holder, a sputtering target, an apparatus for injecting a beam of reactive ions at a chosen energy and directing said ions at said sputtering target, an apparatus for injecting various gases and maintaining an atmosphere of said gases at selected relative concentrations within said chamber;
mounting said read/write head, said plurality of such heads or a magnetic recording medium on said holder;
directing said reactive ion beam at a sputtering target of Si and forming, thereby, a Si layer on said read/write head, said plurality of such heads or said magnetic recording medium; then
forming an atmosphere of O₂ gas and N₂ gas at selected relative concentrations, using Ar as a carrier gas, whereby said O₂ gas oxidizes said Si layer and said N₂ gas nitridizes said Si layer, thereby forming an underlayer of SiOₓN_{y} on said read/write head, said plurality of such heads or said magnetic recording medium.

32. The method of claim 31 wherein said reactive ion beam is a beam of Ar⁺ ions formed by sending said beam through a voltage of between approximately 600V to 1200V.

33. The method of claim 8 wherein the DLC layer is formed by IBD, PECVD or FCVA.

34. The method of claim 8 wherein said underlayer is both adhesion enhancing and corrosion resistant.
